(19) United States
(12) Patent Application Publication
(10) Pub. No.: US 2007/0160102 A1
(43) Pub. Date: Jul. 12, 2007

(54) Vertically emitting, optically pumped semiconductor laser comprising an external resonator

(75) Inventors: Peter Brick, Regensburg (DE); Stephan Lutgen, Regensburg (DE)

Correspondence Address: COHEN PONTANI LIEBERMAN & PAVANE LLP, Suite 1210, 551 Fifth Avenue, New York, NY, 10176, US

(73) Assignee: Orsam Opto Semiconductors GmbH, Regensburg (DE)

(21) Appl. No.: 11/636,949

(22) Filed: Dec. 11, 2006

(30) Foreign Application Priority Data
Dec. 9, 2005 (DE) 10 2005 058 900.6

(51) Int. Cl. H01S 5/00

(52) U.S. Cl. 372/50.124

(57) ABSTRACT

A vertically emitting semiconductor laser comprising an external resonator (7), a semiconductor body (1), and at least one pump radiation source (9). The semiconductor body (1) has a quantum layer structure (2) as an active zone comprising quantum layers (3) and barrier layers (4) lying in between. The semiconductor body (1) furthermore has a Bragg reflector (5) on one side of the quantum layer structure (2). The Bragg reflector (5) comprises layers which are arranged aperiodically with respect to one another in such a way that an absorption of the pump radiation (10) is essentially effected within the quantum layer structure (2).

### RELATED APPLICATIONS

The patent application claims the priority of German Patent Application 102005058900.6 filed Dec. 9, 2005, the disclosure content of which is hereby incorporated by reference.

### FIELD OF THE INVENTION

The invention relates to a vertically emitting semiconductor laser comprising an external resonator, a semiconductor body, and also a Bragg reflector. Situated in the semiconductor body is a quantum layer structure as an active zone containing quantum layers and barrier layers lying in between.

### BACKGROUND OF THE INVENTION

With a vertically emitting semiconductor laser comprising an external resonator, which is also referred to as VECSEL (Vertical External Cavity Surface Emitting Laser), it is possible to realize high output powers in conjunction with high beam quality.

### SUMMARY OF THE INVENTION

One object of the invention is to provide a semiconductor laser of the type mentioned in the introduction having an improved pump efficiency.

This and other objects are attained in accordance with one aspect of the invention directed to a vertically emitting semiconductor laser comprising an external resonator, a semiconductor body, having a quantum layer structure as an active zone comprising quantum layers and barrier layers lying in between, and a Bragg reflector on one side of the quantum layer structure. A pump radiation source is provided for radiating pump radiation into the quantum layer structure. The Bragg reflector comprises layers which are arranged aperiodically with respect to one another in such a way that an absorption of the pump radiation is essentially effected within the quantum layer structure.

In the context of the invention, the term “quantum layer” is to be understood to mean a layer which is dimensioned or structured such that a quantization of the charge carrier energy levels that is essential for the generation of radiation occurs, for example, as a result of confinement. In particular, the designation quantum layer does not comprise any indication about the dimensionality of the quantization. It, therefore, encompasses inter alia, quantum wells, quantum troughs, quantum wires, quantum dots and combinations of said structures.

A typical quantum layer structure has a plurality of quantum layers and barrier layers, the quantum layers generally being significantly thinner than the barrier layers, and in each case at least one barrier layer being arranged between two adjacent quantum layers. Such a structure is also referred to as an RPG structure (Resonant Periodic Gain). In the context of the invention, this is to be understood to mean both (i) structures having a constant distance between adjacent quantum layers and (ii) structures in which the distance between adjacent quantum layers varies. Furthermore, it is also possible to provide even further layers, for example intermediate layers between the quantum layers and the barrier layers, so that for instance a staircase-like energy profile arises. Barrier layers are to be understood here to mean in each case those layers which define the maximum energy of the quantum layer structure, that is to say the energy ranges outside the quantizing structures (quantum wells, quantum wires, etc.).

As a result of the aperiodic embodiment of the Bragg reflector, a spectrally wide resonant absorption of the pump radiation with accompanying increased pump efficiency can be achieved in the semiconductor body. It is furthermore possible to increase the acceptance width with regard to the angle of incidence of the pump radiation.

A suitable layer arrangement of the aperiodic Bragg reflector is found, for example, by calculating the absorption spectrum of the semiconductor body taking account of multiple reflections at layers and interferences. Depending on the parameters of the semiconductor body, in particular the distances, the thicknesses and the composition of all the layers within the semiconductor body, the absorption spectrum has one or a plurality of spectrally wide absorption lines at specific angles of incidence or angle of incidence ranges.

Furthermore, a suitable layer arrangement can be found by calculating spectra which take account of an amplification by stimulated emission in the active zone due to pump radiation being radiated in (amplified reflection).

An optimization of the parameters of the semiconductor body, in particular of the layer distances and/or layer thicknesses of the aperiodic Bragg reflector, with the set objective of obtaining a spectrally broadest possible absorption line at the desired pump radiation wavelength and a reflection that is amplified as greatly as possible at a desired wavelength for the vertical radiation, then leads to a semiconductor laser having a high pump efficiency.

In preferred embodiments, either the absorption of the pump radiation is greater in the quantum layers than in the barrier layers, or else the absorption of the pump radiation is greater in the barrier layers than in the quantum layers. Particularly preferably, there occurs within the semiconductor body a standing wave of the pump radiation whose antinodes of the electric field lie within the quantum layers or within the barrier layers.

With regard to the optical pumping, two complementary pump mechanisms are differentiated, both cases being based on a quantum layer structure having a plurality of quantum layers with barrier layers arranged in between.

In the case of the first pump mechanism, the vertically emitting semiconductor laser is designed, for example, by selection of a suitable pump wavelength in relation to the wavelength in the vertical radiation field, such that the pump radiation is absorbed in the barrier layers arranged between the quantum layers (barrier layer pumping). The absorption of the pump radiation leads to the generation of electron-hole pairs which then occupy the quantum layers' states lying at lower energy levels, so that a population inversion arises in the quantum layers. The vertical radiation is generated by means of said population inversion.

In the case of the second pump mechanism, by contrast, the vertically emitting semiconductor laser is designed such that the pump radiation is absorbed directly in the quantum layers and generates a population inversion directly there (quantum layer pumping).

Consequently, both the method of quantum layer pumping and the method of barrier layer pumping can be used in the context of the invention.

The quantum layers of the quantum layer structure are preferably arranged periodically. The quantum layers are particularly preferably arranged in a plurality of groups, the distance between said groups being greater than the distance between two adjacent quantum layers within a group. In this way, standing wave fields of the pump radiation that form in the semiconductor body can be utilized effectively for pumping.

In one preferred configuration of the invention, the semiconductor body has a front-side layer structure on a side of the quantum layer structure that faces the pump radiation source, which front-side layer structure, in a further configuration, comprises dielectric and/or semi-conducting layers and the layers of which front-side layer structure, in a further advantageous configuration, are arranged aperiodically with respect to one another. The front-side layer structure promotes the formation of standing wave fields.

Preferably, the front-side layer structure is more greatly reflective to pump radiation impinging from the inner side of the semiconductor body than to vertical radiation impinging from the inner side of the semiconductor body and generated by the quantum layer structure. The formation of standing wave fields of the pump radiation is promoted in this way, too.

In a further advantageous configuration of the invention, the semiconductor body has a rear-side reflector on the side of the Bragg reflector that is remote from the pump radiation source. In this way, the formation of standing wave fields of the pump radiation is likewise promoted and the effect achieved is that pump radiation passes through at least the active zone at least twice. The rear-side reflector particularly preferably contains a metallic layer. Metallic layers are distinguished by a high reflectivity with low wavelength dependence and, moreover, have a good thermal conductivity.

Preferably, a heat sink, preferably a metallic heat sink, is arranged on the side of the semiconductor body that is remote from the pump radiation source, particularly together with a metallic layer as rear-side reflector, it is thus possible to achieve a good heat dissipation of the semiconductor body.

The vertically emitting semiconductor laser preferably has an epitaxial semiconductor layer sequence and particularly preferably has an epitaxial semiconductor layer sequence stripped from a growth substrate. In this case, the heat sink may advantageously likewise serve as a carrier.

It is furthermore possible to provide one or a plurality of external pump radiation mirrors which reflect pump radiation emerging from the semiconductor body back into the semiconductor body. A multiple passage of the pump radiation through the active zone may advantageously be provided as a result.

In a further preferred configuration of the invention, the arrangement of the layers of the Bragg reflector is chosen in such a way that the absorption of the pump radiation is effected for a predetermined wavelength λₚ or, particularly preferably, for a wavelength from a wavelength range λₚ±Δλ around the predetermined wavelength λₚ, and a predetermined angle αₚ of incidence of the pump radiation or, particularly preferably, an angle from an angular range αₚ±Δα around the predetermined angle αₚ of incidence, essentially within the quantum layers. Effective quantum layer pumping associated with a small quantum defect is made possible in this way. The wavelength and angle tolerance leads to semiconductor lasers which are simpler to adjust and less temperature-sensitive.

A feature of a further preferred variant of the invention is that the energy difference between the photo energies of the pump radiation and the laser radiation generated by the quantum layer structure is equal to an integer multiple of the energy of a longitudinal optical phonon of the quantum layers. This has the advantage that the electrons from excited pump levels rapidly undergo transition to the upper laser levels through a resonantly amplified emission of a plurality of phonons.

The semiconductor material used is preferably one of the semiconductor materials InₓAl_{y}Ga_{l-x-y}As, InₓAl_{y}Ga_{l-x-y}N, InₓAl_{y}Ga_{l-x-y}P, InₓGaₗ₋ₓAs_{y}N_{l-y} or ZnₓSe_{y} in each case where 0≦x≦1, 0≦y≦1, 0≦x+y≦1. It should be understood that the invention is not restricted to one of said semiconductor materials.

### BRIEF DESCRIPTION OF THE DRAWINGS

FIG. 1 shows a schematically illustrated construction of a vertically emitting semiconductor laser comprising an external resonator according to an embodiment of the invention.

FIG. 2 shows a schematically illustrated construction of a vertically emitting semiconductor laser comprising an external resonator according to a further embodiment of the invention.

FIG. 3 is an illustration of layer thicknesses in an optimized embodiment of the semiconductor body of a laser according to an embodiment of the invention.

FIG. 4 shows calculated spectra of the absorption and the amplified reflection of the semiconductor body illustrated in FIG. 3.

### DETAILED DESCRIPTION OF THE DRAWINGS

Identical or identically acting elements are provided with the same reference symbols in the Figures.

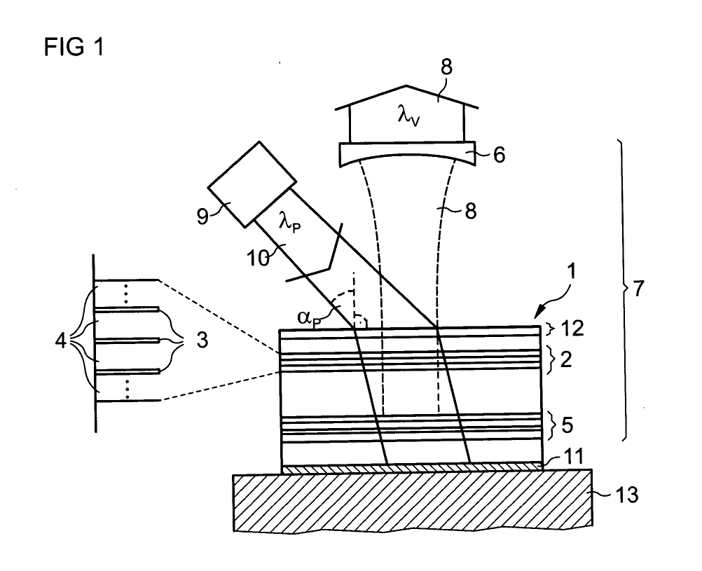

FIG. 1 schematically shows the construction of a vertically emitting semiconductor laser comprising an external resonator in one exemplary embodiment. The laser has a semiconductor body 1, which comprises a quantum layer structure 2 as an active zone having a plurality of quantum layers 3 and barrier layers 4. The barrier layers 4 may involve a combination of a plurality of layers of different semiconductor materials. The semiconductor body 1 furthermore has an aperiodic Bragg reflector 5. The reflector 5 together with an external mirror 6 forms an external resonator 7 for vertical radiation 8 having a wavelength λᵥ. The semiconductor laser is optically pumped by a pump radiation source 9, which radiates pump radiation 10 having a wavelength λₚ into the semiconductor laser 1 at an angle αₚ of incidence. A rear-side reflector 11 is provided on a side of the semiconductor body 1 that is remote from the pump radiation source 9, and a front-side layer structure 12 is provided on a side facing the pump radiation source 9, which layer structure may have one or a plurality of layers. The semiconductor body 1 is connected to a heat sink 13 via the rear-side reflector 11.

The pump radiation source 9 is preferably a semiconductor laser, in particular a diode laser, the wavelength λₚ of the pump radiation 10 being shorter than the wavelength λᵥ of the vertical radiation 8. The pump radiation 10 is typically radiated in obliquely onto the semiconductor body 1, e.g. at an angle of 45°.

A portion of the pump radiation 10 penetrating into the semiconductor body 1 is absorbed by the quantum layer structure 2. Of the non-absorbed portion, a further portion is reflected at the Bragg reflector 5, in particular since the Bragg reflector 5 is embodied aperiodically according to an embodiment of the invention, and therefore has a spectral reflectivity which is not restricted to the vertical wavelength in such narrowband fashion as may be the case with a strictly periodic Bragg reflector having an identical number of layers. The proportion of the pump radiation 10 which is neither absorbed nor reflected by the Bragg reflector 5 is reflected back from the rear-side reflector 11. Said rear-side reflector 11 may be for example an applied metal layer, e.g. made of gold, silver or copper depending on the wavelength λₚ of the pump radiation 10. Via said metal layer, moreover, it is possible to achieve good thermal coupling to the heat sink 13, which may be for example a cooling body or a Peltier element.

Together with the opposite inner interface of the semiconductor body 1, the Bragg reflector 5 and the rear-side reflector 11 form a resonator for the pump radiation 10. The properties of this pump resonator, e.g. its spectral quality factor, are modified by the front-side layer structure layer 12, inter alia. The front-side layer structure 12 may comprise one or a plurality of semiconducting and/or dielectric layers for this purpose. Furthermore, the front-side layer structure 12 may advantageously serve as antireflection coating of the interface of the semiconductor body 1 for the vertical radiation 8.

It should be noted that the pump resonator is also formed without the presence of the front-side layer structure 12, but the front-side layer structure 12 advantageously enables the reflection properties of the interface of the semiconductor body 1 to be manipulated in a targeted manner. It should furthermore be noted that at an angle of incidence of 45°, the pump radiation 10 does not propagate parallel to the resonator axis of the pump resonator in the semiconductor body 1. In this respect, the resonances are strictly speaking quasi-resonances whose wavelength is slightly shifted relative to the natural resonances of the pump resonator. It should be readily apparent that in the context of the invention the pump radiation 10 can also be radiated in parallel to the resonator axis.

The pump resonator gives rise, within the semiconductor body 1, to a standing wave of the pump radiation 10 at whose antinodes of the electric field the layers of the quantum layer structure which absorb the pump radiation 10 preferably lie. They are either the quantum layers 3 or the barrier layers 4 depending on whether quantum layer pumping or barrier layer pumping is used as the pumping method.

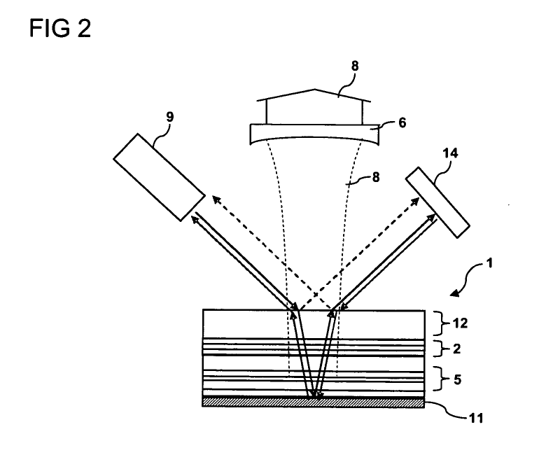

FIG. 2 shows a further exemplary embodiment of a semiconductor laser according to the invention. In addition to elements already described in connection with FIG. 1, an external pump radiation mirror 14 is provided in order to increase the pump efficiency further, which mirror directs pump radiation 10 emerging from the semiconductor body 1 back into the semiconductor body 1. In this way, the pump radiation 10 is lead through the semiconductor body 1 twice. It is also conceivable to provide a plurality of external pump radiation mirrors 14 which form a folded external pump radiation resonator.

A semiconductor laser according to the invention can be produced for example by firstly growing the semiconductor body 1 in the form of an epitaxial semiconductor layer sequence on a growth substrate and subsequently applying the mirror layer on the side remote from the growth substrate. A carrier, which preferably simultaneously serves as a heat sink, is thereupon fixed on the mirror layer and the growth substrate is then removed.

Irrespective of whether barrier pumping or quantum layer pumping is used as the pumping method in the case of the semiconductor laser, for efficient operation of the semiconductor laser a sufficiently high absorption of the pump radiation is required in both cases in order to obtain a high pump efficiency.

In this regard, barrier layer pumping has an advantage over quantum layer pumping since the barrier layers are generally made considerably thicker than the quantum layers and a high absorption of the pump radiation can therefore be achieved more easily.

A loss mechanism that occurs in principal in both pump mechanisms is the relaxation of charge carriers from excited states lying at higher energy levels to the energetically lower radiative levels of the quantum layers. This energy loss, referred to as quantum defect, is manifested in the generation of heat which is emitted to the crystal lattice and thus heats the semiconductor laser in an undesirable manner. The energy loss is proportional to the energy difference between the pump radiation that has a shorter-wavelength and thus higher-energy and the vertical radiation that has a longer-wavelength and thus lower-energy. The maximum output power is thus limited by the maximum permissible thermal loading.

Since a higher energy is required for generating electron-hole pairs in the case of barrier layer pumping, quantum layer pumping is more advantageous with regard to the quantum defect, however. Furthermore, not all of the charge carriers released by the pump radiation in the barrier layers are trapped in the quantum layers, that is to say that the input efficiency is, moreover, less than 1.

It is thus worthwhile to optimize an embodiment of the semiconductor laser according to the invention such that quantum layer pumping with a high absorption of the pump radiation 10 is present.

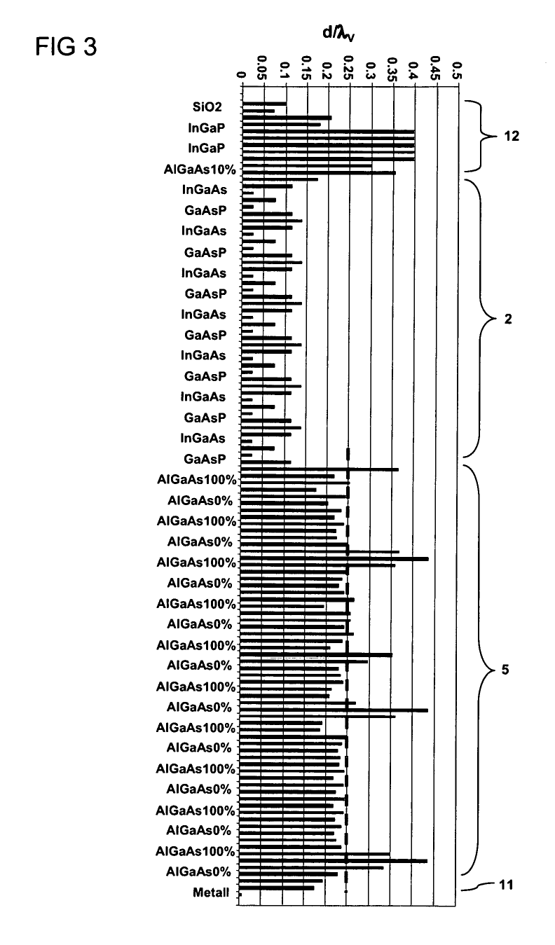

FIG. 3 schematically shows an optimized embodiment of the semiconductor body 1 for a semiconductor laser according to the invention corresponding to FIG. 1. Reference symbols used below correspond to those in FIG. 1.

The laser is designed for vertical radiation 8 having a wavelength λᵥ=1050 nm and for pump radiation 10 having a wavelength λₚ=940 nm, radiated onto the semiconductor body 1 at an angle of incidence of αₚ=45°. The excess energy, that is to say the quantum defect, of the pump radiation is approximately 11%. This value shows that the pump mechanism of optical pumping is quantum layer pumping since significantly greater excess energies of approximately 20% are necessary in the case of barrier layer pumping. The illustration shows optimized layer thicknesses in units of the wavelength λᵥ in the respective material (optical thickness).

The semiconductor body has (from top to bottom in FIG. 3) a rear-side reflector 11 of a material having a thickness of approximately 1 nm, which is followed by a Bragg reflector 5 comprising a sequence of alternately in each case 30 AlAs and 30 AlGaAs layers. This is followed by a quantum layer structure 2 comprising 7 periods. In this case, one period of the quantum layer structure 2 is composed of the following layers in the layer thicknesses specified: GaAsP, 30 nm; InGaAs, 10 nm; GaAsP, 30 nm; InGaAs 10 nm; GaAsP 30 nm and AlGaAs 40 nm. In this case, the InGaAs layers are the quantum layers 3 and the AlGaAs and GaAsP layers are the barrier layers 4. In this case, the GaAsP layers serve for stress compensation. Finally, a front-side layer structure 12 comprising a plurality of InGaP layers and SiN/SiO₂ layers is provided on the quantum layer structure 2.

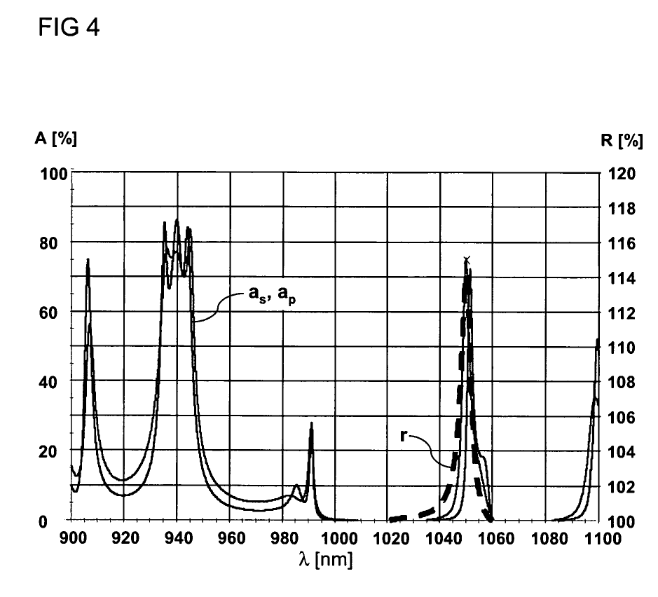

The optical layer thicknesses specified in FIG. 3 are the result of an iterative optimization, based on calculated absorption spectra and spectra of amplified reflection, examples of which are explained in more detail below in connection with FIG. 4. It can clearly be discerned that the layer thicknesses of the Bragg reflector 5 deviate from the layer thickness λᵥ/4 of a periodic Bragg reflector, indicated by the horizontal dashed line. The deviations can be discerned individually for each of the layers; no super ordinate periodicity is discernable. The target criteria for the optimization were a high absorption of the pump radiation 11 in a wide wavelength range (large wavelength acceptance width) in conjunction with high amplified reflection for the vertical radiation 8.

The spectra are calculated with the aid of the so-called transfer matrix method taking account of multiple reflection and absorption at the individual layers. The sequence of layers and also lower and upper limits of the individual layer thicknesses are predetermined in this case. Proceeding from predetermined start values for the layer thicknesses, spectra are then calculated iteratively, and all or a selected group of layer thicknesses are varied such that the target criteria are met as well as possible. In the example shown, the layer thicknesses of the Bragg reflector 5 and of the front-side layer structure 12 were varied for optimization purposes.

FIG. 4 shows calculated absorption spectra aₚ, aₛ and a calculated spectrum of the amplified reflection r for the layer construction of the semiconductor body 1 as illustrated in FIG. 3. The absorption spectra aₚ, aₛ are calculated appropriately for the pump radiation 10 for an angle of incidence of 45° and the spectrum of the amplified reflection r is calculated appropriately for the vertical radiation 8 for an angle of incidence of 0°.

The two absorption spectra aₚ, aₛ, illustrated as thin solid curves, represent the absorption A (left-hand ordinate axis) upon passage through the semiconductor body 1 for radiation which is polarized parallel to the plane of incidence (p-polarization) and for radiation which is polarized perpendicular to the plane of incidence (s-polarization).

The spectrum r, illustrated as a thicker dashed curve, represents the amplified reflection R (right-hand ordinate axis) by the semiconductor body 1. An amplification of the radiation on account of stimulated emission within the quantum layers 3 is concomitantly taken into account in the calculation of the reflection R, which results in a reflection of greater than 100%. Therefore, the calculation in principal represents the semiconductor laser in a pumped state, that is to say during an operational mode the pump radiation 10 is being radiated into the semiconductor laser. The pumped state is incorporated into the calculation by taking account of a charge carrier density in the quantum layers 3. Said charge carrier density is predetermined in parameterized form depending on temperature and depending on the pump light absorption.

A wide absorption structure for p- and s-polarized radiation in the wavelength range around 940 nm is clearly discernable in the absorption spectra aₚ, aₛ. Over a width of approximately 15 nm, the absorption is without exception greater than approximately 70% and on average is approximately 75%. By contrast, absorption lines of comparable semiconductor bodies comprising a periodic Bragg reflector have line widths of approximately 1-2 nm. The semiconductor laser according to the invention thus affords a large wavelength acceptance width for the pump radiation, which leads e.g. to a lower temperature sensitivity.

As shown by the spectrum of the amplified reflection r, an amplified reflection R of more that 115% is achieved at a wavelength of 1050 nm, that is to say at the wavelength λᵥ of the vertical radiation. This value shows that the absorbed energy of the pump radiation 10 is critically converted in an effective pump process, instead of flowing into loss processes (e.g. lattice oscillations, heating).

To summarize, the semiconductor laser according to the invention thus achieves with approximately 75% a high absorption of the pump radiation with a large wavelength acceptance width of 15 nm and an amplified reflection of more than 115% for the vertical radiation for the case of quantum layer pumping with a small quantum defect of approximately 11%. The large wavelength acceptance width is furthermore advantageously accompanied by a large angular acceptance width in the angle of incidence of the pump radiation 10.

It should be readily apparent that a corresponding optimization is also possible for pump radiation whose wavelength preferably leads to the absorption in the barrier layers 4 (barrier layer pumping). The optimization may furthermore be effected such that a weighting of the target criteria is predetermined, or that further target criteria are taken into account.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

We claim:

1. A vertically emitting semiconductor laser comprising:
an external resonator,
a semiconductor body, having a quantum layer structure as an active zone comprising quantum layers and barrier layers lying in between, and a Bragg reflector on one side of the quantum layer structure; and
a pump radiation source for radiating pump radiation into the quantum layer structure,
wherein the Bragg reflector comprises layers which are arranged aperiodically with respect to one another in such a way that absorption of the pump radiation is essentially effected within the quantum layer structure.

2. The vertically emitting semiconductor laser as claimed in claim 1, in which the absorption of the pump radiation is greater in the quantum layers than in the barrier layers.

3. The vertically emitting semiconductor laser as claimed in claim 2, in which there occurs within the semiconductor body a standing wave of the pump radiation whose antinodes of the electric field lie within the quantum layers.

4. The vertically emitting semiconductor laser as claimed in claim 1, in which the absorption of the pump radiation is greater in the barrier layers than in the quantum layers.

5. The vertically emitting semiconductor laser as claimed in claim 4, in which there occurs within the semiconductor body a standing wave of the pump radiation whose antinodes of the electric field lie within the barrier layers.

6. The vertically emitting semiconductor laser as claimed in claim 1, in which the quantum layers of the quantum layer structure are arranged periodically.

7. The vertically emitting semiconductor laser as claimed in claim 1, in which the quantum layers are arranged in a plurality of groups, the distance between said groups being greater than the distance between two adjacent quantum layers within a group.

8. The vertically emitting semiconductor laser as claimed in claim 1, in which the semiconductor body has a front-side layer structure on a side of the quantum layer structure that faces the pump radiation source.

9. The vertically emitting semiconductor laser as claimed in claim 8, in which the front-side layer structure comprises dielectric and/or semiconducting layers.

10. The vertically emitting semiconductor laser as claimed in claim 8, in which the layers of the front-side layer structure are arranged aperiodically with respect to one another.

11. The vertically emitting semiconductor laser as claimed in claim 8, in which the front-side layer structure is more greatly reflective to pump radiation impinging from the inner side of the semiconductor body than to vertical radiation impinging from the inner side of the semiconductor body and generated by the quantum layer structure.

12. The vertically emitting semiconductor laser as claimed in claim 1, in which the semiconductor body has a rear-side reflector on the side of the Bragg reflector that is remote from the pump radiation source.

13. The vertically emitting semiconductor laser as claimed in claim 12, in which the rear-side reflector contains one or a plurality of metallic and/or dielectric layers and/or a further Bragg reflector.

14. The vertically emitting semiconductor laser as claimed in claim 1, in which an external mirror is provided for forming the external resonator.

15. The vertically emitting semiconductor laser as claimed in claim 1, in which at least one external pump radiation mirror is provided which reflects pump radiation emerging from the semiconductor body back into the semiconductor body.

16. The vertically emitting semiconductor laser as claimed in claim 1, in which the layer thicknesses of the Bragg reflector are chosen in such a way that the absorption of the pump radiation is effected for a predetermined wavelength λₚ and a predetermined angle αₚ of incidence of the pump radiation essentially within the quantum layers.

17. The vertically emitting semiconductor laser as claimed in claim 16, in which the predetermined angle αₚ of incidence of the pump radiation lies between 0° and 80°.

18. The vertically emitting semiconductor laser as claimed in claim 16, in which the arrangement of the layers of the Bragg reflector effects the absorption of the pump radiation for pump radiation having a wavelength from a wavelength range λₚ±Δλ around the predetermined wavelength λₚ at the predetermined angle αₚ of incidence of the pump radiation essentially within the quantum layers.

19. The vertically emitting semiconductor laser as claimed in claim 18, in which the wavelength range λₚ±Δλ has a half width Δλ of at least 5 nm.

20. The vertically emitting semiconductor laser as claimed in claims 16, in which the arrangement of the layers of the Bragg reflector effects the absorption of the pump radiation for pump radiation having the predetermined wavelength λₚ within an angular range αₚ±Δα around the predetermined angle αₚ of incidence of the pump radiation essentially within the quantum layers.

21. The vertically emitting semiconductor laser as claimed in claims 20, in which the angular range αₚ±Δα has a half width Δα of at least 5°.

22. The vertically emitting semiconductor laser as claimed in claim 16, in which the arrangement of the layers of the Bragg reflector effects the absorption of the pump radiation for pump radiation having the wavelength from the wavelength range λₚ±Δλ around the predetermined wavelength λₚ within an angular range αₚ±Δα around the predetermined angle αₚ of incidence of the pump radiation essentially within the quantum layers.

23. The vertically emitting semiconductor laser as claimed in claim 22, in which the wavelength range λₚ±Δλ has a half width Δλ of at least 5 nm.

24. The vertically emitting semiconductor laser as claimed in claim 22, in which the angular range αₚ±Δα has a half width Δα of at least 5°.

25. The vertically emitting semiconductor laser as claimed in claim 1, in which the energy difference between the photo energies of the pump radiation and the vertical radiation generated by the quantum layer structure is equal to an integer multiple of the energy of a longitudinal optical phonon of the quantum layers.

26. The vertically emitting semiconductor laser as claimed in claim 1, which, in particular within the quantum layer structure , contains at least one of the semiconductor materials InₓAl_{y}Ga_{l-x-y}As, InₓAl_{y}Ga_{l-x-y}N, InₓAl_{y}Ga_{l-x-y}P, InₓGaₗ₋ₓAs_{y}N_{l-y} or ZnₓSe_{y} in each case where 0≦x≦1, 0≦y≦1, 0≦x+y≦1.

27. The vertically emitting semiconductor laser as claimed in claim 1, comprising an epitaxial semiconductor layer sequence.

28. The vertically emitting semiconductor laser as claimed in claim 27, comprising an epitaxial semiconductor layer sequence stripped from a growth substrate.

29. The vertically emitting semiconductor laser as claimed in claim 1, comprising a heat sink arranged on a side of the semiconductor body that is remote from the pump radiation source.

30. The vertically emitting semiconductor laser as claimed in claim 1, in which the quantum layers are formed as quantum wells, quantum wires, quantum dots or as a combination of said structures.
